(19) United States
(12) Patent Application Publication
(10) Pub. No.: US 2026/0269780 A1
(43) Pub. Date: Sep. 10, 2026

(54) SOLAR-BASED POWER GENERATION MODULES

(71) Applicant: VOLTIRIS SA, Lausanne (CH)

(72) Inventors: Jonas ROCH, Lausanne (CH); Dominik BLASER, Bern (CH)

(21) Appl. No.: 19/167,130

(22) PCT Filed: Mar. 19, 2024
(86) PCT No.: PCT/EP2024/057226

§ 371 Date: Sep. 19, 2025

(30) Foreign Application Priority Data
Mar. 22, 2023 (EP) 23163500.4

(51) Int. Cl. H02S 40/22; A01G 9/24; H02S 20/32

(52) U.S. Cl. CPC H02S 40/22; A01G 9/243; H02S 20/32

(57) ABSTRACT

The present invention relates to Energy generation panel comprising at least two energy generation modules, each energy generation modules comprising a first surface presenting an energy harvesting device, a second surface, a reflecting surface, and a holding structure connecting the first and second surfaces together so as to present a volume in between, wherein the reflecting surface is configured to filter an incident sunlight thereby letting a first portion of said sunlight pass through it and reflecting a second portion of said sunlight, characterized in that said reflecting surface presents a plurality of reflecting regions differently oriented with respect to each other and each being configured to homogeneously reflect said second portion of incident light on a collecting surface of said energy harvesting device.

### TECHNICAL FIELD

The present invention relates to the field of sunlight-based power generation and more particularly to the field of sunlight-based power generation in agriculture. The present invention also aims at providing a means for improving power generation and not impacting agriculture growth.

Preferably, the present invention relates to the field of photovoltaic power generation and spectrally filtering solar energy harvesting module for use in agriculture.

### Background of the Art

Nowadays, Photovoltaic (PV) power generation is seen as a green and low-cost source of energy world-wide as well as a key element paving the way to a fossil energy-free future. However, finding space for large PV projects remains challenging because by creating a PV field, one may either waste arable land or hurt biodiversity by increasing the human footprint. For this reason, modern projects commonly called “Agrivoltaics” have been created which aim at promoting a double use of available land, in which a field of arable land could simultaneously be used for power generation as well as agricultural yield.

It has been shown that agrivoltaics solutions are particularly useful when filtering the light spectrum for optimizing the wavelength reaching the crops. Spectrally filtering agriphotovoltaic solutions are therefore a promising way of generating electricity on arable land without compromising the agricultural yield. It consists in spectrally filtering sunlight, such that the light components needed by the plants are transmitted to the crops, while all the rest of the sunlight is used to generate electricity.

Most existing solar modules based on this technology are made from two distinct elements: (1) a large spectrally-filtering reflector adapted to face the light source and to concentrate the light not needed by the plants onto a (2) photovoltaic cell. Those solar modules are usually mounted onto a two-axis solar tracking mount, and therefore, need to be spatially distant the one to another for permitting rotation while not being hindered by the adjacent ones. While those designs can be benefitting for indoor applications for example inside of greenhouses, they present several drawbacks when used outdoor.

Indeed, for outdoor crop cultivation, it is beneficial to have the largest ground surface coverage to provide protection to weathering to the crops against wind, hail, frost, etc. In addition to that, it has been shown that filtering sunlight can be beneficial to the crops, for instance in terms of water consumption, and pest control. However, a mechanical system with a dual axis solar tracking can only provide a ground surface coverage that is typically around 35-40%. For taking advantages of the agronomical gains listed above, it is necessary to have a solution that can cover 50% or more of the ground surface.

Existing designs based on an approximately 1 m² size solar reflector, when used outdoor, have a high cross-section when exposed to wind. It results in an expensive solar tracking system, and a heavy-duty structure to hold the modules, which ultimately results in a reduction of the light transmission to the crops.

There is therefore a need for such a system which solves the problems recited above.

In this regard, a primary object of the invention is to solve the above-mentioned problems and more particularly to provide a sunlight-based power generation device providing a maximum coverage of the land while not being subject to wind and external forces.

More particularly, a primary object of the invention is to provide a sunlight-based power generation device to be used in agriculture providing a maximum protection to the crop against external aggression such as wind, hail, frost while providing an optimized light transmission and simple holding structures.

Another object of the invention is to provide a system permitting to optimize the energy or power generation at any time of the day and in any season and a mean to control the light quality reaching the crops, with the objective to improve the agronomical yield.

### SUMMARY OF THE INVENTION

The above problems are solved by the present invention which presents a solar module based on spectral filtering that is integrated in a single plane. This planar integration is made from a periodic repetition of small reflectors along one axis into a slab of material. These disclosed planar solar modules solve the problems of prior art: with a planar design, it is possible to mount the system on a 1- or no-solar axis tracking system, allowing for a higher ground surface filling factor, necessary to fully benefit from the advantages of the spectral filtering, and add a crop protection functionality to the spectrally filtering APV system.

The present invention relates to the field of sunlight-based power generation and more particularly to the field of sunlight-based power generation in agriculture. The present invention aims at providing a means for both power generation and agriculture growth optimization.

A first aspect of the invention is an energy generation panel comprising at least two energy generation modules, each energy generation modules comprising a first surface presenting an energy harvesting device, a second surface, a reflecting surface, and a holding structure connecting the first and second surfaces together so as to present a volume in between, wherein the reflecting surface is configured to filter an incident sunlight thereby letting a first portion of said sunlight pass through it and reflecting a second portion of said sunlight, characterized in that said reflecting surface presents a plurality of reflecting regions differently oriented with respect to each other and each being configured to homogeneously reflect said second portion of incident light on a collecting surface of said energy harvesting device.

According to a preferred embodiment of the present invention, the second surface consists in the back surface of the module and the holding structure connects the first and second surfaces together so as to present an inner cavity delimited by the walls, the first and the second surfaces.

Preferably, the reflecting surface is a floating filter located inside the inner cavity of the module.

In a preferred manner, the reflecting surface is a filter laminated/deposited on the second surface.

Alternatively, the reflecting surface is the second surface which presents a filtering composition.

According to a preferred embodiment of the present invention, each module presents a longitudinal shape and are disposed adjacent to each other in a transversal direction.

Preferably, the modules are detachable from each other through reversible attaching means chosen from the group comprising magnetic regions, glue, outer frame and mechanical locking means.

Preferably, the cavity is fully surrounded by the first and second surfaces and the walls.

In a preferred way, the transmission/reflection/refraction of the reflecting surface is adapted through specific materials and/or specific thickness ranges and/or specific surface treatments and/or specific additives so as to be tuned to let pass light with a specific wavelength range.

Preferably, the energy generation panel further comprises an orientation system adapted to modify the orientation of the reflection panel.

According to a preferred embodiment of the present invention, the plurality of reflecting regions are flat and/or adjacent surfaces.

Preferably, the energy harvesting module is chosen in the group comprising one of an electricity generation module using photovoltaic cells, a module for heat generation and a module for hydrogen production.

Preferably, the backside of the energy harvesting device presents a reflecting surface, a light scatterer, contains fluorescent materials and/or an energy-generating surface.

A second aspect of the invention is an orientation-optimization system for orienting an energy generation panel according to the first aspect of the invention accordingly and comprising a panel driving system and a panel driving system control module adapted to control the panel driving system to orient the energy generation panel in order to optimize the electrical or the agronomic yield, i.e. to optimize the quality of crop-reaching light for example by orienting the panel so as to let the light pass at maximum when the daylight is not optimal and protect the crops from heavy rain or strong wind when necessary.

A third aspect of the invention is a light-source tracking system for tracking a light source and orienting an energy generation panel according to the first aspect of the invention accordingly comprising an energy generation panel, a light-source positioning module and a driving system control module adapted to control the panel driving system to orient the energy generation panel according to the detected light source position.

### BRIEF DESCRIPTION OF THE DRAWINGS

Further particular advantages and features of the invention will become more apparent from the following non-limitative description of at least one embodiment of the invention which will refer to the accompanying drawings, wherein

FIG. 1 represents the general concept of the present invention,

FIG. 2 represents a large view of a setup of panels of the invention above crops,

FIG. 3 represents a perspective view of a panel according to a preferred embodiment of the present invention,

FIG. 4 represent a cross view of the panel according to a preferred embodiment of the present invention,

FIGS. 5a to 5d represent cross-section views of four different embodiments of the present invention,

FIG. 6 represents three cross-section views of embodiments of the invention with different reflection types,

FIG. 7 represents an exemplary cross-section view of an embodiment of the present invention with sizes.

### DETAILED DESCRIPTION OF THE INVENTION

The present detailed description is intended to illustrate the invention in a non-limitative manner since any feature of an embodiment may be combined with any other feature of a different embodiment in an advantageous manner.

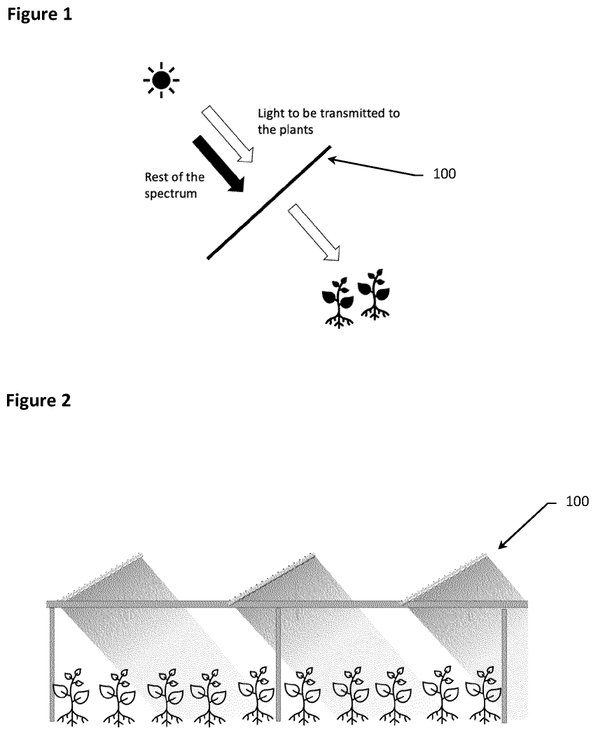

FIG. 1 depicts the general principle of the invention which comprises solar modules 10 adapted to filter sunlight such that the light components, i.e. spectrum, necessary to the plants are transmitted to the crops beneath the panel, and the rest of the light is reflected and redirected to a solar cell adapted to harvest the light to generate energy such as electricity or heat, or even material such as hydrogen, as shown on FIG. 1. In this regard, it has to be noted that blue and red light is particularly useful for the photosynthesis meaning that the light spectrum corresponding to these colors, i.e. approximately 450-495 nm for blue light and 620-750 for red light, shall not be reflected by the reflecting surface 3 while the other bands can be reflected.

More particularly, light with wavelengths from 800 nm to 1250 nm can be reflected onto the energy harvesting device 5 for generating electricity. Near infrared above 1250 nm can also reflected onto the energy harvesting device 5, this is particularly useful in hot climates to protect the crops. It can lead to over-heating of the solar cells, it's use with heat/hydrogen generation shall be preferred. Also, the band between 700 nm and 800 nm (far red) can be reflected for some specific crops, as it can influence the blooming cycles and green light (500 nm-600 nm) can also be reflected as it will have a comparatively small effect on some crops' growth.

More particularly, FIG. 1 shows sunlight directed toward crops and above this land is provided an energy generation device according to the present invention. The term “above” may have its natural meaning, but in the case of vertical farming the same term should be understood as “in front”, in summary the meaning of this term should therefore be understood as “between the plants and the light source” such as the sun. The energy generation device is configured to intercept the sunlight at least partially, with a reflection panel which is adapted to let some light pass to reach the plants and to stop the rest of the light, i.e. the light which is not needed by plants (black arrow), by reflecting it, redirect it and concentrate it homogeneously on an energy generation module 10 (shown later) adapted to produce energy thanks to the reflected light. According to a preferred embodiment, the produced energy is electricity through photovoltaic cell(s), but it can be thermal energy or hydrogen production instead.

More particularly, the energy generation device is configured to permit the light needed for plants' growth to be near-to-fully transmitted to the plants which are therefore located behind (or below) the energy generation device. The passing criteria is preferably the wavelength of the light.

FIG. 2 shows a large view of these modules 10 installed above crops. As we can see the panels are tilted. According to a preferred embodiment the tilt angle can be adapted to maximize the light harvesting yield or the crop growth or both. Indeed, in order to maximize energy, the reflection from the panels needs to be directed towards the energy generating device. This can be achieved by using a 1-D or 2-D solar tracking system, onto which the modules 10 are placed. FIG. 2 shows a possible realization of a 1-D tracking (elevation tracking) onto cultures.

When several panels are installed on structures, each supporting at least one solar energy module 10, are installed, several possibilities may be observed. A first option is to equip each structure with a dedicated actuator and transmission module. Alternatively, a single actuator can be provided, and its motion can be transferred to the other structures to replicate the linear and/or rotational movements on the line containing the actuators.

In connection with invention, one can use a light-source tracking system for tracking a light source, preferably the sun, and for orienting one or several energy panels according to the light source position to optimize and/or maximize the sunlight reception on the panels. This light source tracking system preferably comprises the panel driving system described above as well as a light-source positioning module which can be of any suitable type such as a camera or a light senor or the like, and a driving system control module adapted to control the panel driving system to orient it according to the detected light source position.

The control module may also comprise a processing unit which calculates the optimal orientation of the panels according to several parameters such as season, weather, environment, and the like.

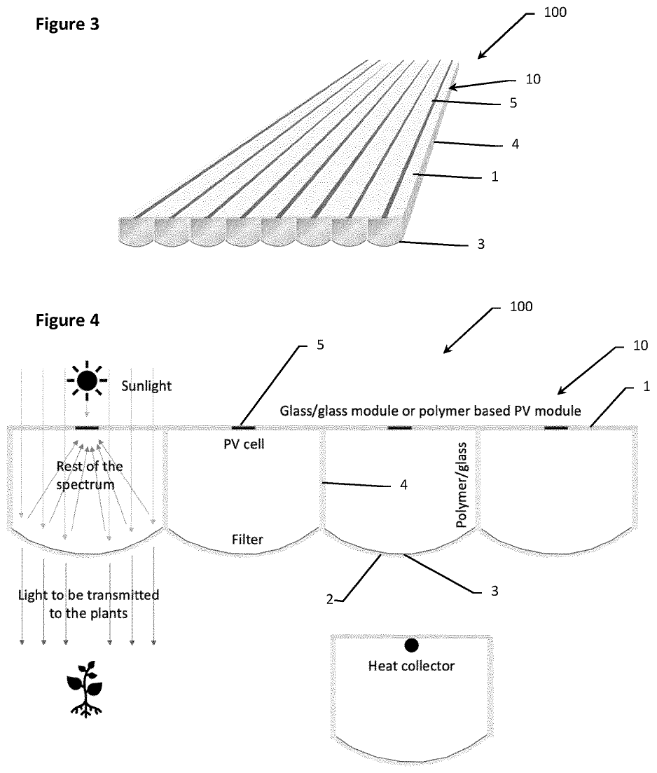

FIG. 3 shows a preferred embodiment of the invention which is an energy generation panel 100 made of several modules 10 adjacent to each other. FIG. 3 shows eight modules 10. However the invention is not limited by any number of modules 10 as it can be adapted to any number according to the field of interest.

The panel shown in FIG. 3 shows the modules 10 disposed next to each other so as to present an overall upper flat surface, however, the modules 10 may be provided so as to present a curved shape or the like.

Also, while the modules 10 may be monobloc and undetachable, it may be provided that the modules 10 are detachable from each other so as to enhance modularity. In such latter case, an attachment/detachment system such as a locking mechanism may be provided. The locking mechanism may comprise magnetic lateral walls, glue, clips, outer frame and the same.

Each module 10 has a longitudinal shape made of a first surface 1, a second surface 2 and a reflecting surface 3 where the second surface 2 and the reflecting surface 3 are beneath the first surface 1 and where the second surface 2 and the reflecting surface 3 may be the same. These surfaces are connected by a holding structure 4 having the form of walls, preferably vertical walls. As we can see the first surface 1 comprises a longitudinal energy harvesting device 5 running all long of the module 10.

FIG. 4 will now describe the panel and the modules 10 in details.

Each module 10 preferably comprises a first surface 1 adapted to let the whole spectrum pass, a second surface 2 and a reflecting surface 3 adapted to reflect part of light and walls 4 made of glass or transparent polymer, connecting the first, the second and the reflecting surfaces 1, 2, 3. As we can see, in a panel, two adjacent modules 10 share a wall. Each module 10 therefore presents a longitudinal shape with either an empty cavity 6 limited by the walls 4 and the first and second surfaces 1, 2 or a filled volume 6, with water or glass for example.

The first surface 1, preferably flat, is preferably made of one material comprised in the group of glass and transparent polymer such as ETFE, i.e. a material adapted to transmit the whole light spectrum, and which is preferably UV light resistant or comprises an additional coating can be used to ensure long lifetime.

The figure shows this surface as a continuous flat surface which basically defines a closed cavity 6 inside the module 10 together with the lower surface and the walls 4. It is important to note that this permits to have the outer surface of the module 10 which can also be treated with an anti-soiling surface treatment to ensure that the modules 10 stay clean at all time. Alternatively, the first surface 1 may consist in a discontinuous surface such a single band having the width of the energy harvesting device 5 and thereby leaving the above mentioned cavity 6 open on the upper side.

This first surface 1 can be called the upper surface as it will always be in front of the light source with respect to the second surface 2. The first surface 1 is adapted to present an energy harvesting device 5 comprising at least one of a PV cell, a heat pipe, a solar activated hydrogen generating medium. Preferably said energy harvesting device 5 has a form which is uniform along the length of the module 10 such as a stripe as shown in FIG. 3.

The energy harvesting device 5 may of course collect the light reflected by the second surface 2, i.e. on its lower side when referring to FIG. 4 but may also be active on the upper side so as to collect light which is directly incident on it.

The second surface 2 is also called lower surface and is disposed under the first surface 1 so as to “close” the lower part of the module 10. By under, it is meant that the second is disposed behind the first surface 1 with respect to the light source.

This reflecting surface 3 is also disposed under the first surface 1 and is adapted to filter the light spectrum so as to let pass a desired range of wavelength as mentioned above and reflect another desired range of wavelength preferably onto the energy harvesting device 5. As we can see from FIGS. 3 and 4, the reflecting surface 3 has a shape, when viewed in a cross-section direction, which is one among a curved smooth or piece-wise flat surface. The major point here is that the reflecting surface 3 presents a plurality of reflecting regions differently oriented with respect to each other and each being configured to homogeneously reflect the chosen portion of incident light on the collecting surface of the energy harvesting device 5.

No particular shape is preferred although FIG. 6 shows three examples. The first one has a reflecting surface 3 presenting a piece-wise parabolic mirror made of several flat portions differently oriented so as to reflect the light onto the lower surface of the energy harvesting device 5. The second example shows a surface having a defocused parabolic shape made of two parabolic surfaces. The third one has a free-shape which reminds that no matter the shape that is chosen, the key feature is having an optimized reflection towards the lower surface of the energy harvesting device 5.

In order to filter the light spectrum, the reflecting surface 3 must present a filtering function. This can be done either by providing a specific composition filtering some portions of the light spectrum to the second surface 2 or by depositing a filter having such function on one of the sides of the second surface 2 or inside the cavity 6 of the module 10, as shown in 5A to 5D.

The filter or the filtering composition should be adapted to let pass blue and red lights which are particularly useful for the photosynthesis meaning that the light spectrum corresponding to these colours, i.e. approximately 450-495 nm for blue light and 620-750for red light, shall not be reflected by the reflecting surface 3 while the other bands can be reflected. Also, the filter can be such as reflecting light with wavelengths from 800 nm to 1250 nm onto the energy harvesting device 5 for generating electricity. The filter should also be adapted to reflect near infrared above 1250nm can onto the energy harvesting device 5 as this is particularly useful in hot climates to protect the crops. Also, the band between 700 nm and 800 nm (far red) should be reflected for some specific crops, as it can influence the blooming cycles and green light (500 nm-600 nm) can also be reflected as it will have a comparatively small effect on some crops' growth. In addition to filtering specific wavelength, the filter or filtering composition can provide some specific pattern such as one diffusing the light onto the crops as diffused light is particularly adapted for homogeneous crop growth.

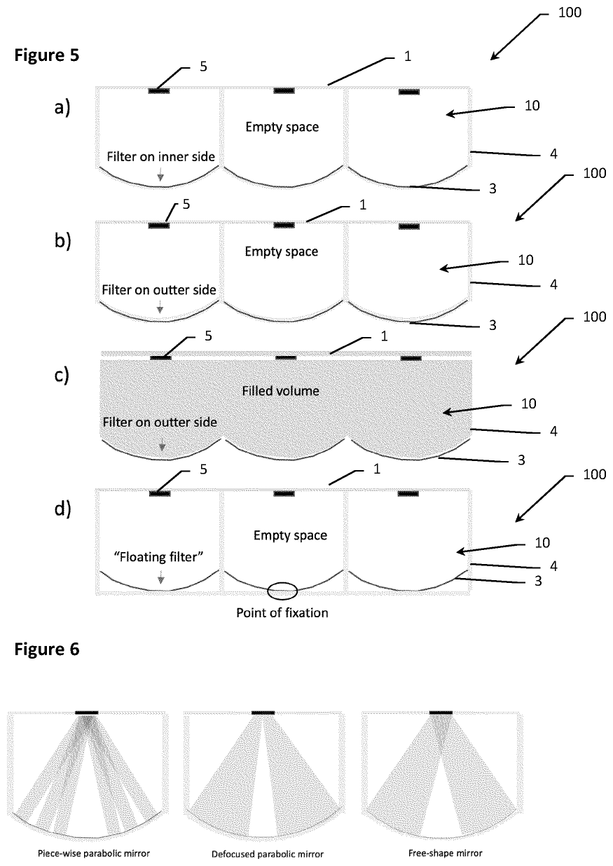

In case of a laminated or deposited filter, FIGS. 5A and 5B show that the reflecting surface 3, here a filter, may be provided on the inner side or outer side of the second surface 2 depending on the manufacturing process to ease its deposition. FIG. 5C shows an embodiment where the volume 6 between the two surfaces is filled, for example with water to collect heat but this may also be “filled” with glass to facilitate the manufacturing process by manufacturing a monolithic glass bar having the shape of the module 10. In such case, the filter is obviously on the lower side of the second surface 2. FIG. 5D represents a particular embodiment where the second surface 2 is not curved but flat as the first one and the reflecting surface 3 is not the lower surface and is provided as a “floating filter” disposed inside the cavity 6. In fact, this shows that the actual shape of the second surface 2 is not crucial, it is the shape of the reflecting surface 3 which is important to homogeneously reflect the chosen portion of incident light on the collecting surface of the energy harvesting device 5.

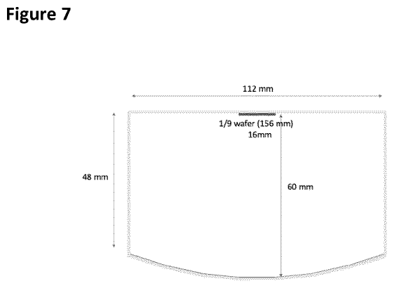

In FIG. 7, possible dimensions of the basic cell of embodiments are provided but they should not limit the invention.

While the embodiments have been described in conjunction with a number of embodiments, it is evident that many alternatives, modifications and variations would be or are apparent to those of ordinary skill in the applicable arts. Accordingly, this disclosure is intended to embrace all such alternatives, modifications, equivalents and variations that are within the scope of this disclosure. This for example particularly the case regarding the different gears, materials, angles which can be used.

Furthermore, it should be intended that the system and the device of the present invention is adapted to be used outdoor, i.e. in an open-field, or indoor, for example, in a greenhouse, and that the power generating device, although it preferably relates to a solar panel may generate energy with a different light source and can be any shape of panel.

1. An energy generation panel comprising at least two energy generation modules, each energy generation module comprising
a first surface presenting an energy harvesting device,
a second surface,
a reflecting surface, and
a holding structure connecting the first and second surfaces together so as to present a volume in between,
wherein the reflecting surface is configured to filter an incident sunlight thereby letting a first portion of said sunlight pass through it and reflecting a second portion of said sunlight,
wherein said reflecting surface presents a plurality of reflecting regions differently oriented with respect to each other and each being configured to homogeneously reflect said second portion of incident light on a collecting surface of said energy harvesting device.

2. The energy generation panel according to claim 1, wherein the second surface consists in the back surface of the module and the holding structure connects the first and second surfaces together so as to present an inner cavity delimited by the walls, the first and the second surfaces.

3. The energy generation panel according to claim 2, wherein the reflecting surface is a floating filter located inside the inner cavity of the module.

4. The energy generation panel according to claim 1, wherein the reflecting surface is a filter laminated or deposited on the second surface.

5. The energy generation panel according to claim 1, wherein the reflecting surface is the second surface which presents a filtering composition.

6. The energy generation panel according to claim 1, one wherein each module presents a longitudinal shape and are disposed adjacent to each other in a transversal direction.

7. The energy generation panel according to claim 1, wherein the modules are detachable from each other through reversible attaching means chosen from the group comprising magnetic regions, glue, outer frame, and mechanical locking means.

8. The energy generation panel according to claim 1, wherein the cavity is fully surrounded by the first and second surfaces and the walls.

9. The energy generation panel to claim 1, wherein at least one of transmission, reflection, and refraction of the reflecting surface is adapted through at least one of specific materials thickness ranges, specific surface treatments, or specific additives so as to be tuned to let pass light with a specific wavelength range.

10. The energy generation panel according to claim 1, wherein it further comprises an orientation system adapted to modify the orientation of the generation panel.

11. The energy generation panel according to claim 1, wherein the plurality of reflecting regions are at least one of flat or adjacent surfaces.

12. The energy generation panel according to claim 1, wherein the energy harvesting module is selected from the group consisting of an electricity generation module using photovoltaic cells, a module for heat generation, and a module for hydrogen production.

13. The energy generation panel according to claim 1, wherein the backside of the energy harvesting device includes at least one of a reflecting surface, a light scatterer, fluorescent materials, or an energy-generating surface.

14. An orientation-optimization system for orienting the energy generation panel of claim 1, wherein the orientation-optimization system includes a panel driving system and a panel driving system control module adapted to control the panel driving system to orient the energy generation panel in order to optimize the electrical or the agronomic yield.

15. A light-source tracking system for tracking a light source and orienting the energy generation panel of claim 1, wherein the light-source tracking system includes an energy generation panel, a light-source positioning module, and a driving system control module adapted to control the panel driving system to orient the energy generation panel according to the detected light source position.
